(19) United States
(12) Patent Application Publication
(10) Pub. No.: US 2026/0254453 A1
(43) Pub. Date: Aug. 27, 2026

(54) HALL ROCKER SWITCH

(71) Applicant: DONGGUAN CITY KAIHUA ELECTRONICS CO.LTD, Dongguan, Guangdong (CN)

(72) Inventors: Fuxi WU, Dongguan, Guangdong (CN); Panhao LV, Dongguan, Guangdong (CN)

(21) Appl. No.: 18/995,391

(22) PCT Filed: Aug. 23, 2023
(86) PCT No.: PCT/CN2023/114339

§ 371 Date: Jan. 16, 2025

(30) Foreign Application Priority Data
Aug. 31, 2022 (CN) 202222330151.6

(51) Int. Cl. H03K 17/97; G05G 5/05; G05G 9/047

(52) U.S. Cl. CPC H03K 17/97; G05G 5/05; G05G 9/04785; G05G 2009/04755; H03K 2017/9706; H03K 2017/9713

(57) ABSTRACT

A Hall rocker switch, comprising: a shell (1), a shaking assembly (2) provided on the shell (1) and having the upper end penetrating through the upper part of the shell (1), a reset member (3) used for driving the shaking assembly (2) to reset, and a PCB (4), and further comprising a magnet (5) linked to the shaking assembly (2), and a Hall chip (6) electrically connected to the PCB (4) and located below the magnet (5), wherein the shaking assembly (2) comprises a support (21) movably arranged on the shell (1), a movable disc (23) arranged in the shell (1), and a rocker seat (22) arranged on the movable disc (23) and movably connected to the support (21). The Hall rocker switch can rotate by 360 degrees to swing, the structure is simplified, resetting is accurate, the service life is long, and the user experience is good.

### TECHNICAL FIELD

The utility model relates to the field of rocker magnetic induction switches, in particular to a Hall rocker switch with high precision, high resolution and long service life.

### TECHNICAL BACKGROUND

In the existing rocker switch, there are two shortcomings:
(1) Poor precision, poor weather resistance, easy drift and short service life, which can't meet users' more demands for functions;
(2) Usually, two groups of carbon brushes are used to realize the output of shaking function, combined with the shaking assembly with two brackets, which is complex and easy to cause unsmooth hand feeling; There are many variable parameters that need to be controlled and controlled in carbon film printing, which is not easy to supervise and can achieve poor consistency of requirements. The carbon brush is a contact part, which will be worn and accompanied by carbon powder impurities during its service life, which will affect the contact performance and drift.

### CONTENT OF UTILITY MODEL

In view of the above shortcomings, the utility model aims to provide a Hall rocker switch, which can realize 360° swing for signal output, and generate signals by the induction of a Hall chip and a magnet. It is a non-contact signal output with simple structure, stable output signal, high precision, long service life and good user experience effect.

The technical scheme adopted by the utility model is as follows:

A Hall rocker switch comprises a shell, a shaking assembly arranged on the shell and the upper end penetrates out of the upper part of the shell, a reset member used for driving the shaking assembly to reset, and a PCB board. It is characterized by also comprising a magnet linked with the shaking assembly, and a Hall chip electrically connected to the PCB board and positioned below the magnet, wherein the shaking assembly comprises a bracket movably arranged on the shell, a movable disc arranged in the shell, and a rocker arranged on the movable disc and movably connected with the bracket, wherein the magnet is arranged at the lower end of the shaking assembly, and the reset member is arranged between the rocker and the movable disc.

As a further improvement of the utility model, the rocker comprises a rocker seat and an operating rod arranged at the upper end of the rocker seat and penetrating through the upper end of the shell, wherein a positioning groove for inserting a movable disc is formed upward at the bottom of the rocker seat.

As a further improvement of the utility model, an upper annular limit groove is formed at the bottom of the rocker seat, and a supporting chassis is arranged at the periphery of the bottom of the movable disc, and a lower annular limit groove is formed on the supporting chassis. The reset member is a spring, and the upper part of the spring is embedded in the upper annular limit groove, and the lower part is embedded in the lower annular limit groove.

As a further improvement of the utility model, an annular reset rib contacting with the bottom of the supporting chassis is formed at the bottom inside the shell.

As a further improvement of the utility model, a convex hull is arranged in the annular reset rib.

As a further improvement of the utility model, an insertion column is extended downward in the positioning groove, a plurality of ribs are arranged between the outer wall of the insertion column and the inner wall of the positioning groove, and a plurality of longitudinal limit grooves are formed by the ribs. A central hole for inserting the insertion column is formed in the middle of the movable disc, and a plurality of longitudinal limit blocks inserted into the longitudinal limit grooves are formed on the side wall of the movable disc.

As a further improvement of the utility model, a countersunk hole is formed upward at the bottom of the plug column, and the magnet is arranged in the countersunk hole.

As a further improvement of the utility model, a movable opening for the rocker seat to be embedded and movable is formed on the bracket, and two opposite ends of the bracket are respectively provided with connecting jacks, and two opposite sides of the rocker seat are respectively provided with a connecting lug in the insert link jack.

As a further improvement of the utility model, a connecting part movably connected with the shell is respectively formed at two opposite ends of the bracket, and two connecting jacks on the bracket are orthogonally arranged with the two connecting parts.

As a further improvement of the utility model, the shell comprises a base and a face shell arranged on the base, the shaking assembly is arranged in an accommodating cavity surrounded by the base and the face shell, and an opening for the upper part of the rocker to pass through is formed on the face shell.

As a further improvement of the utility model, a fixing frame is arranged on the face shell, which fixes the face shell and the base from top to bottom.

As a further improvement of the utility model, a back cover is arranged at the bottom of the base, the PCB board is arranged on the back cover, and a plurality of connecting terminals are welded on the PCB board.

As a further improvement of the utility model, a switch electrically connected to the PCB board is arranged on the base.

The utility model has the beneficial effects that:

A shaking assembly which can rock in X and Y axes and is composed of a bracket, a rocker and a movable disc is combined with a reset member to realize 360°rocking/swinging shaking assembly; Combined with the effect produced by the combination of the magnet and the Hall chip, the rocking rocker drives the magnet to shake, so as to change the moving distance of the magnet, so as to change the number of magnetic induction lines emitted by the magnet penetrating the Hall chip, that is, to change the magnetic flux induced by the Hall chip, convert it into voltage change, and generate pulse signal output, so that the Hall chip can output different signals, and the different signals can define different switching functions, which has multiple functions, and moreover, the action accuracy of each structure is high. Good stability, long service life and good user experience effect. For example, the voltage change signal in the displacement direction of the rocker can be applied to the movement direction and displacement of the characters/objects of the game machine.

The shaking assembly is composed of a bracket, a rocker and a movable disc, and can be combined with the conduction mode formed by the combination of magnets and Hall chips. Because the Hall chip can sense signals in three directions of x, y and z, the signal output is not hindered. Compared with the traditional method of using a complex carbon brush conduction structure with two brackets to drive the X and Y axes, the Hall chip can realize 360° rotation only by driving one bracket, so that the structure is greatly simplified, the hand feel is smooth, the signal output is stable, the resolution is high, the phenomenon of drift does not occur, and the weather resistance is high, and the service life is long.

The signal output between the magnet and the Hall chip is an inductive signal output, and the signal output generated by non-carbon brush contact greatly prolongs the service life compared with the previous contact output, which solves the problem that the traditional carbon brush is worn after contact friction, and after wear, there will be residues at the contact position, which will lead to unstable contact and drift.

The above is an overview of the technical scheme of the utility model, and the following is a further explanation of the utility model with the attached drawings and specific embodiments.

### BRIEF DESCRIPTION OF DRAWINGS

FIG. 1 is an exploded view of the utility model;

FIG. 2 is a schematic diagram of the overall external structure of the utility model;

FIG. 3 is a sectional view of the utility model;

FIG. 4 is a partial structural diagram of the utility model;

FIG. 5 is a schematic structural diagram of the bracket in the utility model;

FIG. 6 is a schematic structural diagram of the rocker in the utility model;

FIG. 7 is a bottom view of the rocker in the utility model;

FIG. 8 is a schematic structural diagram of the movable disc in the utility model;

FIG. 9 is another structural schematic diagram of the utility model.

### EMBODIMENT

In order to further explain the technical means and effects adopted by the utility model to achieve the predetermined purpose, the specific implementation of the utility model will be described in detail with the attached drawings and preferred embodiments.

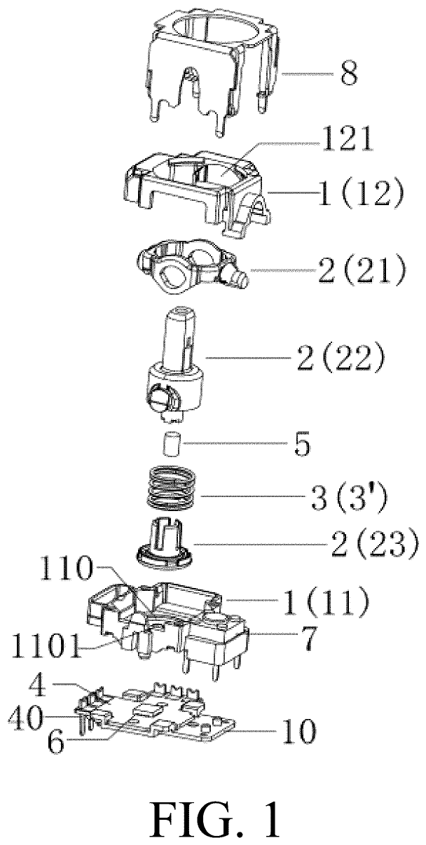

Please refer to FIG. 1 to FIG. 3. An embodiment of the utility model provides a Hall rocker switch, which comprises a shell 1, a shaking assembly 2 arranged on the shell 1 and having an upper end penetrating the upper part of the shell 1, a reset member 3 for driving the shaking assembly 2 to reset, and a PCB board 4. The Hall rocker switch of this embodiment further includes a magnet 5 linked with the shaking assembly 2, and a Hall chip 6 electrically connected to the PCB 4 and located below the magnet 5. Specifically, the Hall chip 6 can be soldered on the PCB 4. The shaking assembly 2 drives the magnet 5 to shake, so that the distance between the magnet 5 and the Hall chip 6 changes, which changes the magnetic flux induced by the Hall chip 6, that is, changes the magnetic flux, which is converted into voltage changes after being induced by the Hall chip 6, so as to output different signals and realize different functions of increasing and decreasing. Specifically, in the static state where the shaking assembly 2 is centered, the Hall chip 6 senses and takes it as a reference point. After the magnet 5 swings, the distance between the magnet 5 and the Hall chip 6 changes, and after the magnet 5 generates a change in magnetic flux, the Hall chip 6 senses and converts it into a variable voltage output signal.

In this embodiment, the shape and size of the magnet 5 can be set according to the specific situation, and it is necessary to meet the requirement that the magnetic flux is greater than 200 GS. The magnet 5 is cylindrical, with a diameter of 2.0 mm and a height of 3.5 mm or more. The static distance between the magnet 5 and the Hall chip 6 is 1.2 mm or less.

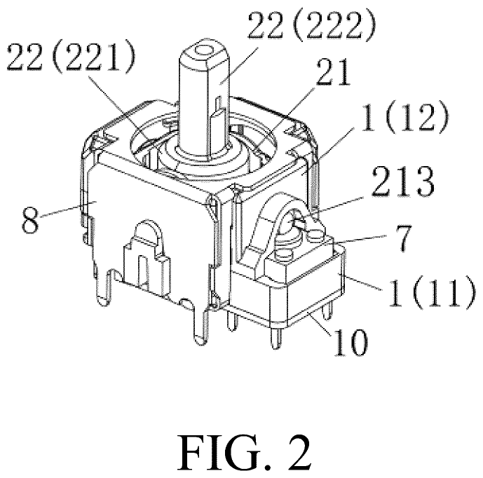

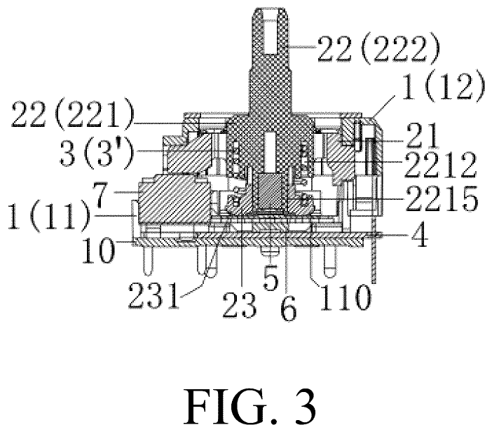

In this embodiment, as shown in FIG. 2 and FIG. 3, the shaking assembly 2 includes a support 21 movably arranged on the shell 1, a movable disc 23 arranged in the shell 1, and a rocker 22 movably connected with the support 21 and arranged on the movable disc 23. The upper end of the rocker 22 passes through the shell for a customer to set a knob, wherein the magnet 5 is arranged at the lower end of the shaking assembly 2, and the reset member 3 is arranged between the rocker 22 and the movable disc 23. The reset member 3 provides restoring force for the rocking of the rocker 22 and the movable disc 23, so that the rocker 22 and the movable disc 23 can be restored to the initial state after each rocking. When the rocker 22 is shaken, the magnet 5 is driven to shake synchronously, and the Hall chip 6 senses the change of magnetic flux and converts it into the change of voltage, and the signal is output through the 6 connecting terminals 40 on the PCB 4.

Specifically, the upper part of the magnet 5 is an N pole and the lower part is an S pole. The magnetic induction lines around the magnet 5 come out from the N pole and enter the S pole. After the magnetic induction lines come out from the N pole, some magnetic induction lines will penetrate the Hall chip 6 and then enter the S pole, and the magnetic induction lines penetrating the Hall chip 6 will be induced by the Hall chip 6.

When the rocker 22 drives the magnet 5 to swing in different directions and at different angles, the number of magnetic induction lines penetrating the Hall chip 6 will change, and the magnetic flux induced by the Hall chip 6 will change, so that the Hall chip 6 can output different signals, generate different voltage changes, and define different switching functions, for example, menu selection, volume adjustment, direction selection and so on.

In this embodiment, the shaking assembly 2 with special structural design is combined with the reset member 3, so that the shaking assembly 2 can be rocked in 360°; Combined with the arrangement of the magnet 5 and the Hall chip 6, the shaking assembly 2 drives the magnet 5 to shake, so as to change the number of magnetic induction lines emitted by the magnet 5 penetrating the Hall chip 6, that is, to change the magnetic flux induced by the Hall chip 6 and convert it into voltage change, so that the Hall chip 6 can output different signals, and different signals can define different switching functions.

The Hall chip 6 in this embodiment is a conventional Hall chip in the field, and the model can be KTH5701, but other models can also be selected.

In this embodiment, as shown in FIG. 2 to FIG. 4 and FIG. 6, the rocker 22 includes a rocker seat 221 and an operating lever 222 which is arranged at the upper end of the rocker seat 221 and penetrates the upper end of the shell 1, wherein a positioning groove 2211 is formed upward at the bottom of the rocker seat 221 for inserting the movable disc 23, and the movable disc 23 is inserted into the positioning groove 2211, so that the two can closely cooperate to slide up and down and can be prevented. The arrangement of the movable disc 23 provides positioning and homing function for the rocker 22, and combined with the reset member 3, the rocker 22 can be homing to the central vertical position, that is, the initial state, after the operation is completed.

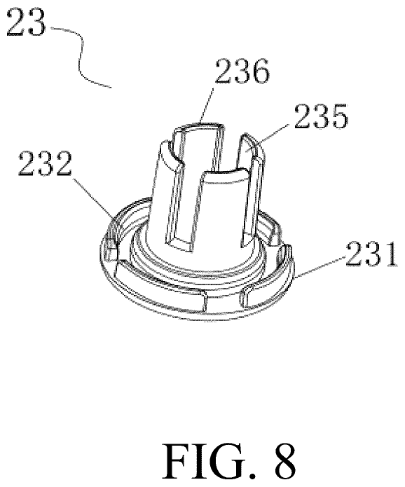

Regarding the installation of the reset member 3, as shown in FIGS. 3, 6 and 8, an upper annular limiting groove 2212 is formed at the bottom of the rocker seat 221, which is circumferentially arranged around the periphery of the positioning groove 2211, a supporting chassis 231 is arranged around the bottom of the movable disc 23, and a lower annular limiting groove 232 is formed on the supporting chassis 231. The reset member 3 is a spring 3′, and the upper part of the spring 3′ is embedded in the upper annular limiting groove 2212. The lower part is embedded in the lower annular limit groove 232 to limit the deformation range of the spring 3′, so that the spring 3′ only elastically deforms in the vertical direction, and can reset up and down without lateral movement. Therefore, accurate elastic restoring force can be provided for the rocking of the rocker 22, which is conducive to improving the accuracy of the action of the entire shaking assembly 2.

In this embodiment, the support 21 and the rocker 22 are movably arranged in the shell 1 to swing, and the movement and reset of the rocker 22 are driven by the combination of the movable disc 23 and the spring 3′. When the rocker 22 swings, it drives the movable disc 23 to slide together. When the movable disc 23 swings to the limit position, the arc surface at the bottom of the movable disc 23 can reset the rocker 22 after releasing it under the restoring force of the spring 3′.

The up-and-down telescopic movement of the movable disc 23 and the bottom of the rocker 22 is operated by the spring 3′, and the whole resetting action is very smooth and has a long service life.

In this embodiment, an annular reset rib 110 contacting with the bottom of the supporting chassis 231 is formed at the inner bottom of the shell 1. Specifically, the annular reset rib 110 is formed at the inner bottom of the following base 11, as shown in FIG. 3. Since the bottom of the supporting chassis 231 contacts with the ring-shaped reset rib 110, when the supporting chassis 231 of the movable disc 23 rocks with the rocker 22, the homing of the movable disc 23 is slightly deviated, and it is guided and corrected by the ring-shaped reset rib 110, so that the homing of the movable disc 23 is more accurate, thereby improving the centering accuracy of the product.

At the same time, a convex hull 1101 is arranged in the ring-shaped reset rib 110, which plays a smooth reset role for the large swing action of the rocker 22 and the movable disc 23, and can slide down to reset without locking, thus preventing the occurrence of jamming.

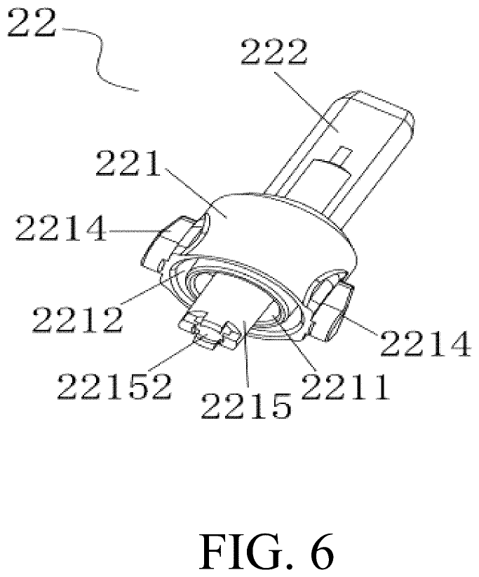

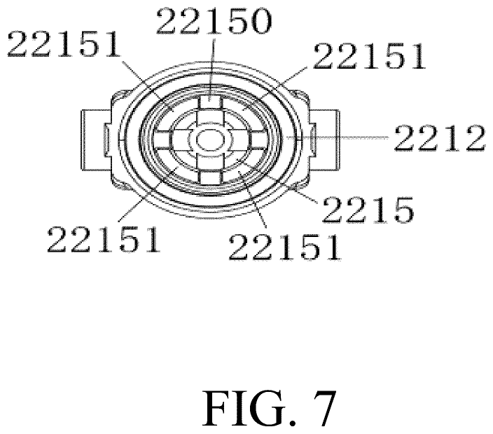

As shown in FIGS. 6 to 8, an insertion post 2215 is extended downward in the positioning groove 2211. A plurality of rib positions 22150 are arranged between the outer wall of the insertion post 2215 and the inner wall of the positioning groove 2211. A plurality of longitudinal limit grooves 22151 are separated by the plurality of rib positions 22150. A central hole 235 for the insertion of the insertion post 2215 is formed in the middle of the movable disc 23. A plurality of longitudinal limiting blocks 236 inserted into the longitudinal limiting grooves 22151 are formed on the side wall of the movable disc 23. The pin 2215 is inserted into the central hole 235, and the longitudinal stop block 236 is inserted into the longitudinal stop groove 22151, so that the movable disc 23 and the rocker seat 221 of the rocker 22 can be tightly and stably installed, and there will be no rotational movement between them, which plays a role of limit. When the rocker 22 rocks, the position of the magnet 5 changes and drives the movable disc 23 to rotate 360°. After letting go, the reset member 3 can make the rocker 22 return smoothly and accurately.

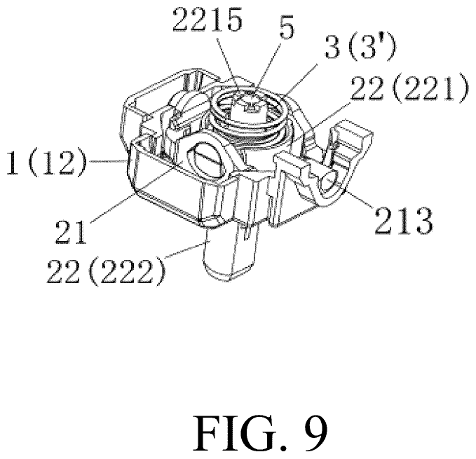

For the installation of the magnet 5, as shown in FIG. 3, FIG. 6 and FIG. 9, a countersunk hole 22152 is formed upward at the bottom of the insert post 2215, and the magnet 5 is arranged in the countersunk hole 22152.

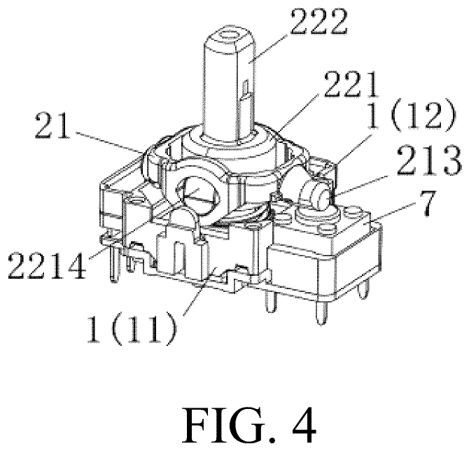

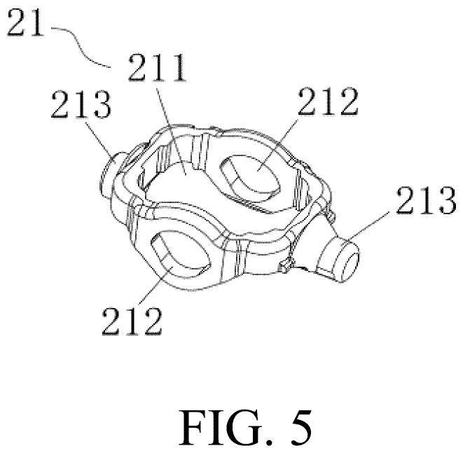

Regarding the combination of the support 21 and the rocker 22, as shown in FIGS. 4 to 6, in this embodiment, a movable opening 211 is formed on the support 21 in which the rocker seat 221 is inserted and moved, and a connection jack 212 is formed on opposite ends of the support 21 respectively. A connection lug 2214 inserted into the connection jack 212 is respectively provided on opposite sides of the rocker seat 221, and the connection lug 2214 is inserted into the connection jack 212. realize the movable connection of the rocker seat 221 and the support 21. At the same time, a connecting part 213 movably connected with the shell 1 is respectively formed at two opposite ends of the support 21, and two connecting jacks 212 on the support 21 are orthogonally arranged with the two connecting parts 213, so that the support 21 is movably connected with the shell 1 and the rocker 22 respectively.

When rocking the rocker 22 in a certain direction, a corresponding force is applied to the support 21, which makes the support 21 swing adaptively, so that the rocker 22 can swing 360° on the X and Y axes. The support 21 in this embodiment not only supports the rocker 22, but also limits the swing amplitude of the rocker 22, thus making the rocker 22 swing more smoothly and accurately.

In this embodiment, as shown in FIGS. 1 and 2, the shell 1 includes a base 11 and a face shell 12 arranged on the base 11. The shaking assembly 2 is arranged in an accommodating cavity surrounded by the base 11 and the face shell 12, and an opening 121 for the upper part of the rocker 22 to pass through is formed on the face shell 12.

At the same time, a fixing frame 8 is arranged on the face shell 12, and the fixing frame 8 fixes the face shell 12 and the base 11 from top to bottom to complete the assembly of the whole product, and then the whole product is installed on the corresponding product to realize the function of the Hall rocker switch.

Meanwhile, in this embodiment, the movable disc 23 is in contact with the inner bottom of the base 11, and the movable disc 23 can be confined in the annular restoring rib 110 of the base 11 after the face shell 12 is combined with the fixing frame 8.

In this embodiment, as shown in FIGS. 2 and 3, a switch 7 electrically connected to the PCB board 4 is arranged on the base 11, specifically, the switch 7 is located below the connecting part 213 of the support 21. When the rocker 22 is rocked, the connecting part 213 will act on the switch 7, so that the switch 7 will be turned on, and the switch 7 will provide a sense of touch for the rocking action. Of course, other functions can also be defined for the switch 7. Under normal conditions, the switch is closed.

In this embodiment, as shown in FIGS. 1 to 3, a back cover 10 is arranged at the bottom of the base 11, and the PCB board 4 is arranged on the back cover 10. At the same time, a plurality of connection terminals 40 are welded on the PCB board 4, and the number of connection terminals 40 can be 6, which can also be increased or decreased as needed to connect the PCB board of the client. Specifically, the connecting terminal 40 is inserted into the terminal hole on the PCB board 4, and then welded and fixed on the upper end face. The capacitor, resistor and Hall chip 6 are welded on the PCB board 4, and then installed on the bottom of the base 11. Finally, the back cover 10 is covered, and the switch 7 is inserted for assembly.

During assembly, the magnet 5 is assembled in the semi-finished products of the assembled support 21 and the rocker 22. The magnet 5 is installed at the position of the rocker 22, pressed to the bottom, and then the upper end is hot riveted. After hot riveting, the glue will fix and block the magnet 5 to prevent the phenomenon of displacement or falling off during the working process. Then it is assembled with the face shell 12, so that the support 21 is sleeved on the face shell 12, and then the spring 3′ is installed at the bottom of the rocker 22, as shown in FIG. 9. Finally, that assemble movable disc 23, the switch 7, the PCB board 4 and the base 11 of the back cover 10 are assemble into a whole, and the assembly is completed by putting on the fixing frame 8.

What needs to be explained here is that the Hall rocker switch disclosed in this utility model is an improvement on the specific structure, but it is not an innovation of this utility model for the specific control mode. The PCB board, magnet, Hall chip, switch and other parts involved in this utility model can be common standard parts or parts known to technicians in this field, and their structures, principles and control methods are known to technicians in this field through technical manuals or through conventional experimental methods.

The above is only the preferred embodiment of this utility model, and it does not limit the technical scope of this utility model. Therefore, other structures obtained by adopting the same or similar technical features as the above embodiments of this utility model are within the protection scope of this utility model.

What is claimed is:

1. A Hall rocker switch comprises a shell (1), a shaking assembly (2) arranged on the shell (1) and with the upper end penetrating out of the upper part of the shell (1), a reset member (3) used for driving the shaking assembly (2) to reset, and a PCB board (4). It is characterized in that it also comprises a magnet (5) linked with the shaking assembly (2), and a Hall chip (6) electrically connected to the PCB board (4) and located below the magnet (5). The shaking assembly (2) comprises a support (21) movably arranged on the shell (1), a movable disc (23) arranged in the shell (1), and a rocker (22) arranged on the movable disc (23) and movably connected with the support (21), wherein the magnet (5) is arranged at the lower end of the shaking assembly (2), and the reset member (3) is arranged between the rocker (22) and the movable disc (23).

2. The Hall rocker switch according to claim 1, wherein the rocker (22) comprises a rocker seat (221) and an operating rod (222) arranged at the upper end of the rocker seat (221) and penetrating through the upper end of the shell (1), wherein a positioning groove (2211) for inserting the movable disc (23) is formed upward at the bottom of the rocker seat (221).

3. The Hall rocker switch according to claim 2, wherein an upper annular limit groove (2212) is formed on the bottom of the rocker seat (221), which is circumferentially arranged on the periphery of the positioning groove (2211), a supporting chassis (231) is arranged on the periphery of the bottom of the movable disc (23), a lower annular limit groove (232) is formed on the supporting chassis (231), and the reset member (3) is a spring (3′). The upper part of the spring (3′) is embedded in the upper annular limit groove (2212), and the lower part is embedded in the lower annular limit groove (232).

4. The Hall rocker switch according to claim 3, wherein an annular reset rib (110) is formed at the bottom of the shell (1) and is in contact with the bottom of the support chassis (231).

5. The Hall rocker switch according to claim 4, wherein a convex hull (1101) is arranged in the annular reduction rib (110).

6. The Hall rocker switch according to claim 2, wherein an insertion post (2215) is arranged to extend downward in the positioning groove (2211), a plurality of rib positions (22150) are arranged between the outer wall of the insertion post (2215) and the inner wall of the positioning groove (2211), and a plurality of longitudinal limit grooves (22151) are separated by the plurality of rib positions (22150). A central hole (235) for inserting the insertion column (2215) is formed in the middle of the movable disc (23), and a plurality of longitudinal limit blocks (236) inserted into longitudinal limit grooves (22151) are formed on the side wall of the movable disc (23).

7. The Hall rocker switch according to claim 6, wherein a countersink hole (22152) is formed upward at the bottom of the insertion post (2215), and the magnet (5) is disposed in the countersink hole (22152).

8. The Hall rocker switch according to claim 2, characterized in that a movable opening (211) for the rocker seat (221) to be inserted and moved is formed on the support (21), and a connection jack (212) is formed on opposite ends of the support (21), and a connection lug (2214) inserted into the connection jack (212) is respectively provided on opposite sides of the rocker seat (221).

9. The Hall rocker switch according to claim 8, wherein a connecting part (213) movably connected with the shell (1) is formed at opposite ends of the support (21), and two connecting jacks (212) on the support (21) are arranged orthogonally to the two connecting parts (213).

10. The Hall rocker switch according to claim 1, wherein the shell (1) comprises a base (11) and a face shell (12) arranged on the base (11), the shaking assembly (2) is arranged in an accommodation cavity surrounded by the base (11) and the face shell (12), and an opening (121) through which the upper part of the rocker (22) passes is formed in the face shell (12).

11. The Hall rocker switch according to claim 10, wherein a fixing bracket (8) is arranged on the face case (12), and the fixing bracket (8) fixes the face case (12) and the base (11) from top to bottom.

12. The Hall rocker switch according to claim 10, wherein a back cover (10) is arranged at the bottom of the base (11), the PCB board (4) is arranged on the back cover (10), and a plurality of connecting terminals (40) are soldered on the PCB board (4).

13. The Hall rocker switch according to claim 10, wherein a switch (7) electrically connected to the PCB board is arranged on the base (11).
